(19) United States
(12) Patent Application Publication
(10) Pub. No.: US 2023/0115807 A1
(43) Pub. Date: Apr. 13, 2023

(54) RADAR DEVICE AND METHOD FOR CONTROLLING RADAR DEVICE

(71) Applicant: SONY SEMICONDUCTOR SOLUTIONS CORPORATION, Kanagawa (JP)

(72) Inventors: Keigo BUNSEN, Kanagawa (JP); Qixian SHI, Leuven (BE); Jan CRANINCKX, Leuven (BE)

(73) Assignee: SONY SEMICONDUCTOR SOLUTIONS CORPORATION, Kanagawa (JP)

(21) Appl. No.: 17/802,617

(22) PCT Filed: Feb. 22, 2021
(86) PCT No.: PCT/JP2021/006631

§ 371 Date: Aug. 26, 2022

(30) Foreign Application Priority Data
Mar. 4, 2020 (JP) 2020-036368

(51) Int. Cl. G01S 13/34; G01S 13/58; G01S 7/40

(52) U.S. Cl. CPC G01S 13/343; G01S 7/4008; G01S 13/584

(57) ABSTRACT

A radar device includes a transmission unit that transmits an FMCW signal, a reception unit that receives the FMCW signal which is transmitted by the transmission unit and reflected by an object, a measurement unit that measures a spurious of the FMCW signal, and a signal control unit that controls the FMCW signal transmitted by the transmission unit on the basis of a measurement result of the measurement unit.

### TECHNICAL FIELD

The present disclosure relates to a radar device and a method for controlling the radar device.

### BACKGROUND ART

As a radar device, a radar device such as an FMCW radar transceiver is known (see, for example, Patent Documents 1 to 3) .

### CITATION LIST

### Patent Document

Patent Document 1: Japanese Patent Application Laid-Open No. 2010-71899
Patent Document 2: Japanese Patent Application Laid-Open No. 2017-227460
Patent Document 3: Japanese Patent Application Laid-Open No. 2016-54381

### SUMMARY OF THE INVENTION

### Problems to Be Solved by the Invention

In a radar device such as an FMCW radar transceiver, spurious occurs due to a frequency error generated in an FMCW signal (e.g., a chirp signal).

An object of one aspect of the present disclosure is to provide a radar device capable of suppressing a spurious, and a method for controlling the radar device.

### Solutions to Problems

A radar device according to one aspect of the present disclosure includes: a transmission unit that transmits an FMCW signal; a reception unit that receives the FMCW signal which is transmitted by the transmission unit and reflected by an object; a measurement unit that measures a spurious of the FMCW signal; and a signal control unit that controls, on the basis of a measurement result of the measurement unit, the FMCW signal transmitted by the transmission unit.

A method for controlling a radar device according to one aspect of the present disclosure is a method for controlling a radar device that transmits and receives an FMCW signal, the method including: measuring a spurious of the FMCW signal; and controlling the FMCW signal on the basis of the spurious measured.

### BRIEF DESCRIPTION OF DRAWINGS

FIG. 1 is a diagram illustrating an example of the schematic configuration of a radar device according to an embodiment.

FIG. 2 is a diagram illustrating an example of the schematic configuration of a PLL.

FIG. 3 is a diagram conceptually illustrating control of an FMCW signal.

FIG. 4A is a diagram illustrating an example of a relationship between frequency resolution of a PLL and SFDR.

FIG. 4B is a diagram illustrating an example of a spectrum.

FIG. 4C is a diagram illustrating an example of a spectrum.

FIG. 5A is a diagram illustrating a relationship between a sweep bandwidth shift amount and SFDR.

FIG. 5B is a diagram illustrating an example of a spectrum.

FIG. 6 is a diagram illustrating an example of spurious suppression processing.

FIG. 7 is a diagram illustrating the schematic configuration of a radar device according to a modification example.

### MODE FOR CARRYING OUT THE INVENTION

Hereinafter, embodiments of the present disclosure will be described in detail with reference to the drawings. Note that, in each of the following embodiments, the same parts are denoted by the same reference signs, and redundant description will be omitted.

The present disclosure will be described according to the following order of items.
1. Embodiment
   1.1 Example of Schematic Configuration of Radar Device
   1.2 Example of Schematic Configuration of PLL
   1.3 Example of Control of FMCW Signal
   1.4 Principle of Improving Spurious Characteristic by Control of FMCW Signal
   1.5 Example of Spurious Suppression Processing
2. Modification Example
3. Effects

### 1. Embodiment

### 1.1 Example of Schematic Configuration of Radar Device

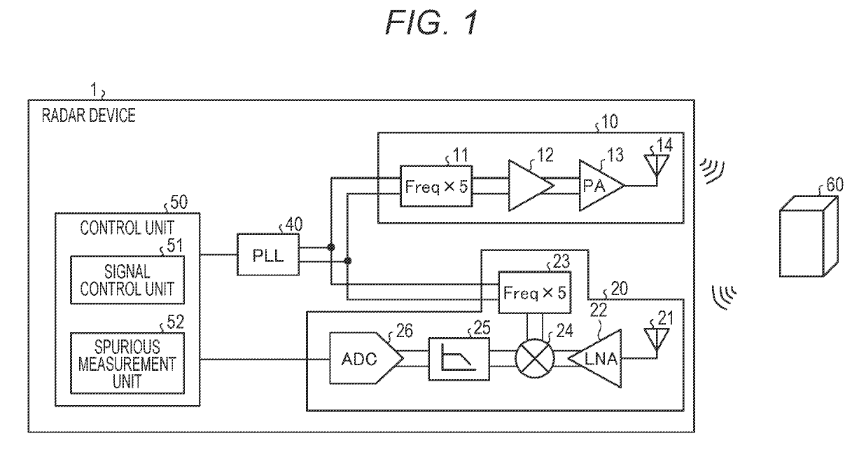

FIG. 1 is a diagram illustrating the schematic configuration of a radar device according to an embodiment. The radar device 1 is, for example, an FMCW radar transceiver, and utilizes a frequency modulated continuous wave (FMCW) signal. An example of the FMCW signal is a chirp signal. Examples of the chirp signal include an up chirp signal and a down chirp signal. The radar device 1 illustrated in FIG. 1 includes a transmission unit 10, a reception unit 20, a phase locked loop (PLL) 40 and a control unit 50.

The transmission unit 10 transmits the FMCW signal. In this example, the transmission unit 10 includes a multiplier 11, a buffer 12, a power amplifier (PA) 13, and an antenna 14. The multiplier 11 is also referred to as a frequency multiplier, and increases the frequency of the signal (PLL signal) from the PLL 40 by an integral multiple (five times in this example). The PLL signal is a signal frequency-modulated so as to constitute an FMCW signal or a signal based on the FMCW signal. The buffer 12 and the PA 13 amplify the FMCW signal whose frequency has been increased by the multiplier 11. The antenna 14 transmits (emits) the FMCW signal amplified by the buffer 12 and the PA 13.

The FMCW signal emitted by the antenna 14 is at least partially reflected by an object 60 and received by an antenna 21 (described later). Examples of the object 60 include a car, a person, a building, and the like.

The reception unit 20 receives the FMCW signal. In this example, the reception unit 20 includes an antenna 21, an LNA 22, a multiplier 23, a mixer 24, a filter 25, and an ADC 26. The antenna 21 receives the FMCW signal reflected by the object 60. The LNA 22 amplifies the FMCW signal received by the antenna 21. The multiplier 23 increases the frequency of the PLL signal from the PLL 40 by the same integral multiple as the multiplier 11. By using the PLL signal whose frequency has been increased by the multiplier 23, the mixer 24 converts (e.g., down-converts) the frequency of an RX signal amplified by the LNA 22. The FMCW signal after the frequency conversion is referred to as an IF signal or the like. The filter 25 filters the IF signal generated by the mixer 24. In this example, the filter 25 is a low-pass filter. The ADC 26 converts the IF signal filtered by the filter 25 into a digital signal.

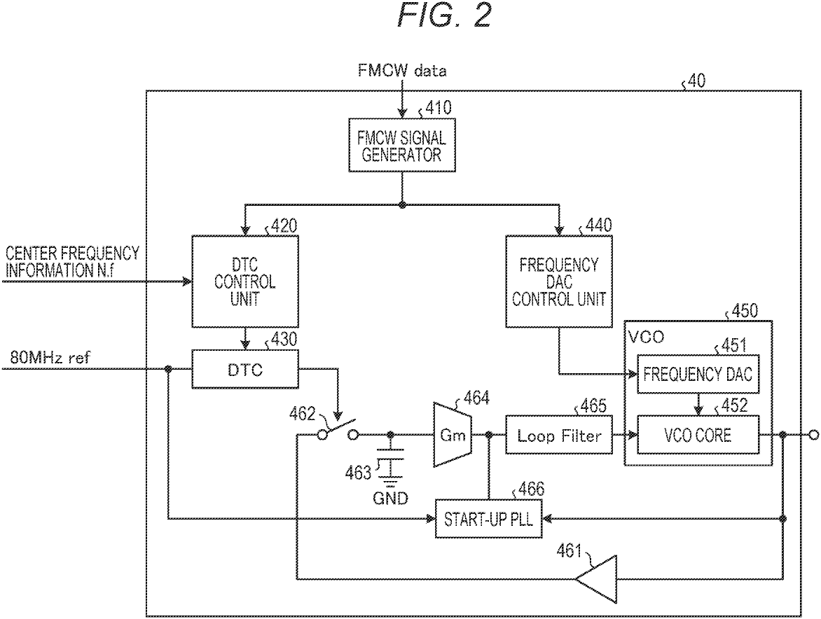

The PLL 40 is a frequency synthesizer that generates a signal having a desired frequency, and is a phase locked loop in this example. The details of the PLL 40 will be described later with reference to FIG. 2.

The control unit 50 is a unit that performs overall control of the radar device 1. For example, the control unit 50 controls the radar device 1 so that the radar device 1 functions as an FMCW radar transceiver. In this case, the control unit 50 detects the distance between the radar device 1 and the object 60 on the basis of the IF signal. Since a distance detection method on the basis of the IF signal is known, a detailed description will not be given herein.

The above-described configuration of the radar device 1 is an example and may be changed as appropriate. For example, the transmission unit 10 and the reception unit 20 do not necessarily have to include the multiplier 11 and the multiplier 23. The antenna 14 and the antenna 21 each include a plurality of antennas and phase shifters, and may be capable of changing directivity. Alternatively, the antenna 14 and the antenna 21 may be combined and constituted by a single antenna, and the radar device 1 may be configured such that transmission and reception by the antenna can be switched. Various known configurations including such configurations may be adopted.

### 1.2 Example of Schematic Configuration of PLL

FIG. 2 is a diagram illustrating an example of the schematic configuration of the PLL 40. In the example shown in FIG. 2, the PLL 40 includes a FMCW signal generator 410, a DTC control unit 420, a DTC 430, a frequency DAC control unit 440, a VCO 450, a buffer 461, a switch 462, a capacitor 463, a converter 464, a loop filter 465, and a start-up PLL 466. The VCO 450 includes a frequency DAC 451 and a VCO core 452.

The FMCW signal generator 410 generates an FMCW signal on the basis of FMCWDdata supplied from a signal control unit 51 (described later) of the control unit 50. The FMCWdata includes parameter information on the FMCW signal. The parameters will be described later.

The DTC control unit 420 generates a control signal suitable for the input of the DTC 430 on the basis of the FMCW signal from the FMCW signal generator 410 and the center frequency information N.f. Processing such as nonlinearity compensation may be performed together. The center frequency information N.f is supplied from the signal control unit 51. The center frequency information N.F is also an aspect of the above-described parameter information.

The DTC 430 is a digital-to-time converter and changes a delay amount of a reference signal (80 MHz in this example) on the basis of a control signal from the DTC control unit 420.

The frequency DAC control unit 440 converts the FMCW signal generated by the FMCW signal generator 410 into a control signal suitable for an input into the frequency DAC 451. Processing such as nonlinearity compensation may be performed together.

The VCO 450 is a transmitter that performs frequency modulation on the basis of a control signal from the frequency DAC control unit 440. In the VCO 450, the frequency DAC 451 converts the control signal from the frequency DAC control unit 440 into a signal suitable for voltage application to the VCO core 452. The VCO core 452 generates a signal having a frequency corresponding to the voltage applied from the frequency DAC 451. The signal generated by the VCO core 452 is output as the PLL signal described above and supplied to the multiplier 11 and the multiplier 23 (FIG. 1).

A part of the signal (PLL signal) generated by the VCO core 452 returns to the VCO core 452 through the buffer 461, the switch 462, the converter 464, and the loop filter 465. The capacitor 463 is connected in parallel between the input terminal of the converter 464 and the ground. The converter 464 converts the output of the buffer 461 held in the capacitor 463 from a voltage to a current. The loop filter 465 filters the converted current.

The switch 462 is connected in series between the buffer 461 and the converter 464. The switch 462 is opened at the timing of the reference signal delayed by the DTC 430 and plays a role of holding the output voltage of the buffer 461 at the timing in the capacitor 463.

The start-up PLL 466 is a block that operates at the time of start-up to assist the phase lock, and is provided so as to form a loop by the VCO core 452, the start-up PLL 466, and the loop filter 465 in this example. After the phase lock, the start-up PLL 466 may be turned off (to terminate the operation).

The PLL 40 illustrated in FIG. 2 as an example is a two-point modulation PLL in which frequency modulation can be performed at two locations. The first frequency modulation is performed by the FMCW signal generator 410, the DTC control unit 420, and the DTC 430. That is, the PLL signal is subjected to frequency modulation by the DTC430 changing a delay amount of the reference signal on the basis of FMCWdata. The second frequency modulation is performed by the FMCW signal generator 410, the frequency DAC control unit 440, and the VCO 450. That is, in the VCO 450, the frequency DAC 451 changes the voltage applied to the VCO core 452 on the basis of the FMCWdata, thereby subjecting the PLL signal to frequency modulation.

The radar device 1 described above is required to generate an FMCW signal having a small frequency error with respect to a sweep frequency. The frequency error appears as noise in the IF signal in the reception unit 20, for example. An example of the noise is spurious biased to some frequencies. Such spurious cannot be distinguished from the object 60 to be measured, and causes erroneous detection. Therefore, there is a demand for spurious suppression.

A main factor of the spurious generation is quantization noise caused by the frequency resolution of the PLL 40. The quantization noise in this case indicates a frequency error generated by rounding the frequency of the PLL signal actually generated by the PLL 40 to the resolution with respect to the desired frequency set in the PLL 40 by the control unit 50. In the radar device 1 using the FMCW signal, for example, since the frequency is linearly modulated unlike a modulation signal close to random used in wireless communication, quantization noise tends to have repeatability (reproducibility), thereby generating spurious.

For example, an FMCW signal (more specifically, a chirp signal) that is ideally linearly modulated is compared with an FMCW signal generated with a finite frequency resolution of 80 kHz and a reference cycle interval (frequency update interval) of 12.5 nsec. In this case, the frequency error is generated by two factors. The first factor is an error in the time direction due to the finite frequency update interval. The second factor is an error in the frequency direction due to the finite frequency resolution. Although a frequency error occurs in these combinations, most of the error generated by the first factor appears in a high frequency component, and thus, can be removed by a filter (e.g., the filter 25 of the reception unit 20), and the influence on the radar characteristics is small. On the other hand, since the error generated by the second factor also appears in a low frequency component, the error cannot be removed by the filter, and it is difficult to eliminate the influence on the radar characteristics.

Meanwhile, in recent years, in order to improve the performance of an in-vehicle radar and expand applications of the radar to gesture recognition usage and the like, there has been a demand for widening the sweep bandwidth of the FMCW signal, accelerating the sweep time, and the like. The widening of the sweep bandwidth leads to an improvement in distance resolution. The acceleration in the sweep time leads to an improvement in the maximum detection speed. However, since these demands and an increase in the frequency error are in a trade-off relationship, the spurious is in an increasing direction. In particular, in order to respond to a request for shortening the sweep time (a request for increasing the speed of the sweep), a frequency synthesizer configured as two-point modulation such as the PLL 40 described above is being developed, but in this case, a larger spurious is likely to occur. This is because it is difficult to increase the resolution of the frequency DAC 451 that directly modulates the VCO core 452 of the VCO 450, and this quantization noise tends to be large.

Therefore, a spurious suppression method capable of coping with widening of a sweep bandwidth, shortening the sweep time (acceleration of a sweep), and the like is demanded. In particular, a simple spurious suppression method without enlarging the circuit scale or increasing the power consumption is desirable. According to the radar device 1 according to one aspect of the present disclosure, such a spurious suppression method is realized.

Returning to FIG. 1, the control unit 50 will be further described. The control unit 50 controls the FMCW signal transmitted by the transmission unit 10. For this purpose, the control unit 50 includes a signal control unit 51 and a spurious measurement unit 52.

The signal control unit 51 controls the FMCW signal. For example, the signal control unit 51 controls the FMCW signal by changing the parameter of the FMCW signal. In a case where the FMCW signal is a chirp signal, examples of types of parameters are a sweep bandwidth, a sweep time (chirp time), and a center frequency. Examples of values of the parameters include a magnitude of a sweep bandwidth, a length of a sweep time, and a value of a center frequency. The magnitude of the sweep bandwidth, the length of the sweep time, and the value of the center frequency may be absolute values, or may be a shift amount with respect to a predetermined value (e.g., an initial value). The shift amount may be, for example, a minute amount such as less than 1% or less than 0.1 percent. Note that, in the example of FIG. 2 described above, the information on the parameters related to the sweep bandwidth and the sweep time is included in the FMCWdata. The parameter related to the center frequency is included in the center frequency information N.f.

### 1.3 Example of Control of FMCW Signal

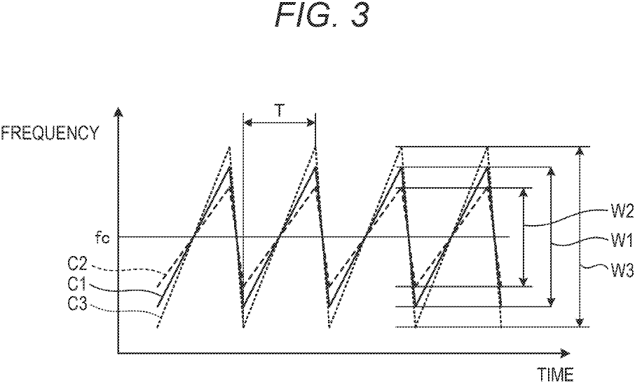

FIG. 3 is a diagram conceptually illustrating the control of the FMCW signal. In the graph of FIG. 3, the horizontal axis represents time, and the vertical axis represents frequency. In this example, the FMCW signal is a chirp signal, and the parameter to be controlled is a sweep bandwidth. As illustrated in graph lines C1 to C3, the FMCW signal is controlled to exhibit three different behaviors. The sweep time (chirp time) T and the center frequency fc exemplified as other parameters are the same in any FMCW signals.

The FMCW signal indicated by the graph line C1 is swept with a sweep bandwidth W1. The FMCW signal indicated by the graph line C2 is swept with a sweep bandwidth W2 that is less than the sweep bandwidth W1. The FMCW signal indicated by the graph line C3 is swept with a sweep bandwidth W3 that is greater than the sweep bandwidth W1. That is, the sweep bandwidth W1 to the sweep bandwidth W3 are sweep bandwidths specified by parameters so that each has a different magnitude.

Besides the sweep bandwidth, FMCW signals may be generated, each having a different sweep time T. An FMCW signal may be generated, each having a different center frequency fc. FMCW signals with different combinations of the sweep bandwidth, the sweep time T and the center frequency fc may be generated.

Returning to FIG. 1, the signal control unit 51 controls the FMCW signal on the basis of a measurement result (described later) of the spurious measurement unit 52. Specifically, the signal control unit 51 controls the FMCW signal so as to improve the spurious characteristic of the FMCW signal. An example of the spurious characteristic is a spurious free dynamic range (SFDR). However, the present disclosure is not limited thereto, and various spurious characteristics determined with respect to the performance of the radar device 1 may be used. The control of the FMCW signal is performed by changing the type and/or value (hereinafter, it may be simply referred to as a “parameter”) of the parameter of the FMCW signal, for example, as described above with reference to FIG. 3. A plurality of different parameters may be prepared in advance, and in this case, the signal control unit 51 may select a parameter having the best spurious characteristic within the range of the measurement result of the spurious measurement unit 52 from a plurality of predetermined parameters.

The spurious measurement unit 52 is a portion that measures the spurious of the FMCW signal. Specifically, the spurious measurement unit 52 measures the spurious of the FMCW signal on the basis of the IF signal converted into the digital signal by the ADC 26. For example, the spurious measurement unit 52 measures the spectrum of the IF signal by executing fast Fourier transform (FFT) on the digital IF signal, and measures the spurious of the FMCW signal from the spectrum. Since the IF signal is a signal generated on the basis of the FMCW signal, the spectrum of the IF signal substantially indicates the spectrum of the FMCW signal. In this sense, in the present specification, the spurious/spectrum of the FMCW signal and the spurious/spectrum of the IF signal may be interchangeably read as appropriate.

### 1.4 Principle of Improving Spurious Characteristic by Control of FMCW Signal

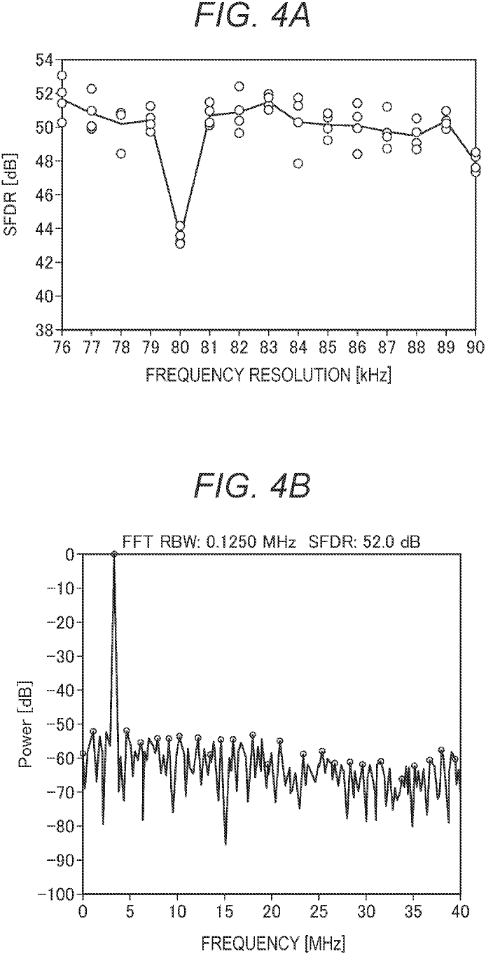

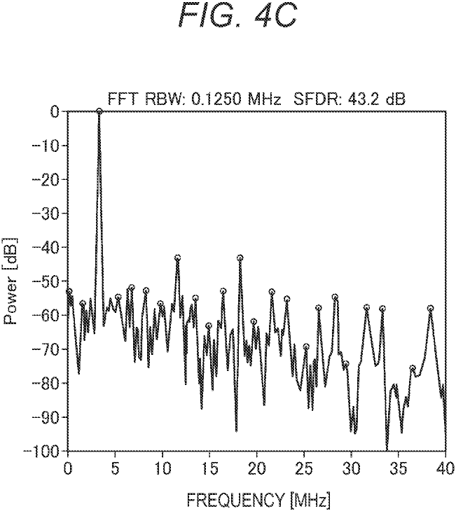

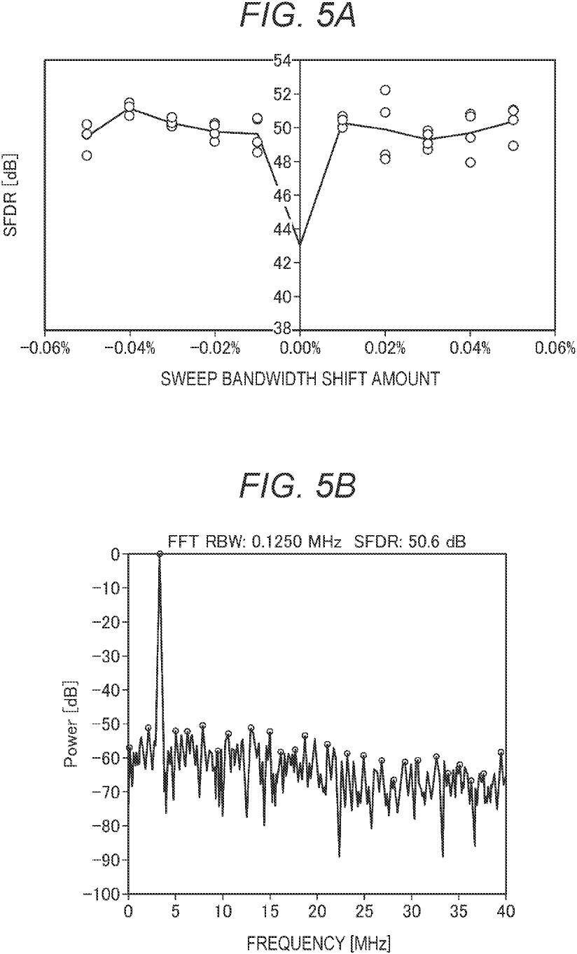

The relationship between the control of the FMCW signal by the above-described signal control unit 51 and the spurious characteristic of the FMCW signal will be described with reference to FIGS. 4A to 4C, 5A, and 5B.

FIG. 4A is a diagram illustrating an example of a relationship between frequency resolution of an FMCW signal and SFDR. This graph illustrates SFDR in a case where the frequency resolution of the FMCW signal generated by the configuration of the PLL 40 illustrated in FIG. 2 is changed. The sweep bandwidth of the FMCW signal in the simulation is 1 GHz. The sweep time is 10 microseconds. The center frequency is about 79.2 GHz. The horizontal axis of the graph represents the frequency resolution (kHz). The vertical axis of the graph represents SFDR (dB). The simulation is performed four times under the same condition for each frequency resolution, each value is plotted with a white dot, and the average value of these values is indicated by a solid line. The SFDR is a value calculated from a spectrum obtained by executing FFT with a frequency resolution (RBW: Resolution Band Width) of 0.1250 MHz on the FMCW signal (IF signal) after the down-conversion.

As illustrated in FIG. 4A, the SFDR changes depending on the frequency resolution. For example, in a case where the frequency resolution is 83 kHz, a high SFDR of about 52 dB is obtained. FIG. 4B is a graph illustrating a spectrum in a case where the frequency resolution is 83 kHz. The horizontal axis of the graph represents the frequency (MHz). The vertical axis of the graph represents power (dB). On the vertical axis, the magnitude of the power of the signal having the main frequency component corresponds to 0 dB. As shown in FIG. 4B, the noise level is kept low over the frequency range of 0 to 40 MHz.

Referring to FIG. 4A again, for example, in a case where the frequency resolution is 80 kHz, the SFDR becomes the worst (the worst case), and a low value of only about 43 dB can be obtained. FIG. 4C is a graph illustrating a spectrum in a case where the frequency resolution is 80 kHz. As shown in FIG. 4C, frequency components having a high noise level are scattered in a range of a frequency of 0 to 40 MHz. As a result, in a case where the frequency resolution is 80 kHz, the SFDR is degraded by 9 dB as compared with a case where the frequency resolution is 83 kHz.

Considering the relationship between the frequency resolution and the spurious characteristic as described above, it is conceivable to set the frequency resolution (83 kHz in the above example) at which high SFDR can be obtained as a design target value. However, the frequency resolution during the actual operation of the radar device is affected by manufacturing variations, temperature characteristics, and the like, and deviates from the target value (an error occurs). For example, when the frequency resolution becomes 80 kHz as described above, the spurious characteristic of the radar device is significantly deteriorated.

Herein, even in a case where the SFDR deteriorates due to the operation with the specific frequency resolution as described above, the SFDR is improved by changing the parameter of the FMCW signal as described above with reference to FIG. 3. In this regard, a case where the sweep bandwidth is shifted will be described below as a parameter change example.

FIG. 5A is a graph illustrating a relationship between a sweep bandwidth shift amount and SFDR in a case where the frequency resolution is 83 kHz. The horizontal axis of the graph represents the sweep bandwidth shift amount (%). The vertical axis of the graph represents SFDR (dB). The initial value of the sweep frequency is 1 GHz. The sweep time and the center frequency are similar to those in the examples of FIGS. 4A to 4C described above. As illustrated in FIG. 5A, it can be seen that SFDR changes when the sweep bandwidth shift amount is changed. For example, it is found that the SFDR is improved to about 51 dB by only shifting the sweep bandwidth by + 0.02% (that is, + 200 kHz). FIG. 5B is a graph illustrating a spectrum in a case where the bandwidth shift amount is + 0.02%. It can be seen that the spectrum shown in FIG. 5B has a low noise level over the range of the measurement frequency 0 to 40 MHz compared with the spectrum shown in FIG. 3B (a case where the sweep bandwidth shift amount is 0.00%, that is, an initial value) described above.

As described above, even in a case where the spurious characteristic such as SFDR is deteriorated due to the error in the frequency resolution, the spurious characteristic can be improved by changing the value of the sweep bandwidth (in this example, shifting the value of the sweep bandwidth). The spurious characteristic is improved by changing not only the sweep bandwidth but also the sweep time, the center frequency, and the like described above.

On the basis of the above principle, the signal control unit 51 controls the FMCW signal such that the spurious characteristic measured by the spurious measurement unit 52 is improved (e.g., the SFDR is increased). Specifically, the signal control unit 51 changes the parameter of the FMCW signal. The signal control unit 51 controls the PLL 40 such that the FMCW signal corresponding to the changed parameter is generated. The spurious measurement unit 52 measures the spurious (more specifically, of the IF signal) of the FMCW signal transmitted by the transmission unit 10 and received by the reception unit 20. The signal control unit 51 controls the FMCW signal by selecting a parameter that minimizes the spurious measured by the spurious measurement unit 52. By using the FMCW signal controlled in this manner (parameter setting), the spurious is suppressed.

In a case where the above-described principle is utilized, for example, as illustrated in FIG. 5A described above, the shift amount of the sweep bandwidth only needs to be a minute amount of less than 0.1 percent. Therefore, by suppressing the shift amount to an amount that does not exceed the ratio of the FFT resolution with respect to the FFT frequency range (0.1250 MHz ÷ 40 MHz = about 0.3% in the case of FIG. 5B), the signal processing circuit (circuits after the multiplier 11) at the subsequent stage can operate without being affected by the shift amount. Therefore, there is also an advantage that the FMCW signal control method as described above can be easily implemented in the radar device. The same applies to the shift amount of the sweep time, the center frequency and the like.

### 1.5 Example of Spurious Suppression Processing

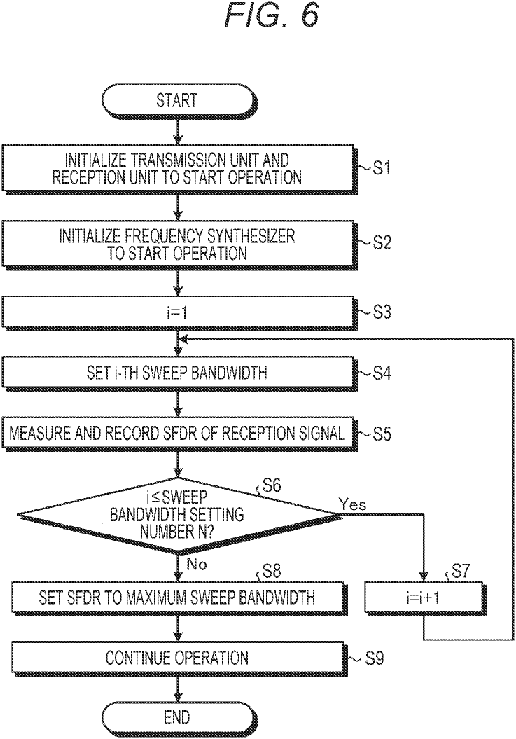

FIG. 6 is a flowchart illustrating an example of spurious suppression processing (a method for controlling a radar device). In this example, the FMCW signal is controlled by changing the sweep bandwidth. The processing of this flowchart is executed, for example, before (e.g., immediately before) the control unit 50 starts using the radar device 1. Since the details of the control by the control unit 50 have been described so far, the description thereof will not be repeated herein.

In Step S1, the transmission unit 10 and the reception unit 20 are initialized, and the operation starts. Specifically, the gains of the buffer 12, the PA 13, and the LNA 22 are set, and enable is turned on.

In Step S2, the frequency synthesizer is initialized, and the operation starts. Specifically, an FMCW signal on the basis of the initial value of the parameter is generated by the PLL 40 and transmitted by the transmission unit 10. Moreover, the FMCW signal reflected by the object 60 is received by the reception unit 20.

The processing in Steps S3 to S8 is processing for searching for an optimal parameter. In this example, a loop process using the integer variable i is executed to measure the SFDR of each of the predetermined N sweep bandwidth.

In Step S3, 1 is substituted for the integer variable i.

In Step S4, the i-th sweep bandwidth of the preset N sweep bandwidths is set.

In Step S5, the FMCW signal corresponding to the sweep bandwidth set in Step S4 described above is generated, transmitted and received, and the SFDR is measured and recorded.

In Step S6, it is determined whether or not i is N or less. In a case where i is N or less (Yes in Step S6), the processing proceeds to Step S7. Otherwise, if i is greater than N (No in Step S6), the processing proceeds to step S8.

In Step S7, i is increased (i = i + 1). When the processing in Step S7 ends, the processing returns to Step S4.

In Step S8, the sweep bandwidth with the maximum SFDR is set to the sweep bandwidth of the FMCW signal. Herein, the sweep bandwidth with the largest SFDR is the sweep bandwidth corresponding to the largest SFDR measured in Step S5 during the loop of previous Steps S4 to S7.

In Step S9, the operation of the radar device continues. That is, the FMCW signal swept with the sweep bandwidth set in Step S8 described above is generated, and the generated FMCW signal is transmitted and received, thereby detecting the object 60 (FIG. 1) or the like.

After the processing of Step S9 is completed, the processing of the flowchart ends.

For example, by operating the radar device 1 by using the sweep bandwidth in which the SDFR is maximized as described above, the spurious can be suppressed. The same applies to parameters other than the sweep bandwidth.

Note that, in the above flowchart, an example in which the sweep bandwidth is set at the start of the operation of the radar device 1 has been described, but the present disclosure is not limited thereto, and the sweep bandwidth may be set during the operation of the radar device. For example, the processing of Steps S3 to S9 may be periodically executed from the start to the end of the operation. As a result, it is possible to suppress the spurious due to an error in frequency resolution caused by heat or the like between the operation start time and the operation end time of the radar device.

### 2. Modification Example

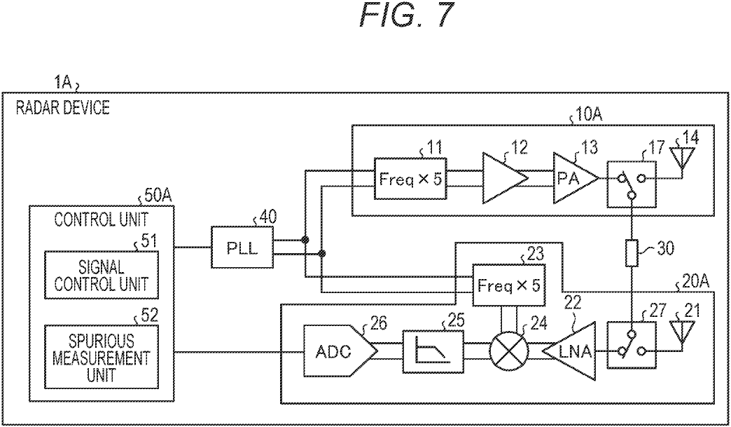

In the above embodiment, an example of measuring the spurious of the FMCW signal after being emitted by the antenna 14 has been described. However, the spurious of the FMCW signal before being emitted by the antenna 14 may be measured. FIG. 7 is a diagram illustrating an example of the schematic configuration of a radar device according to such a modification example.

A radar device 1A illustrated in FIG. 7 is different from the radar device 1 (FIG. 1) in that a transmission unit 10A, a reception unit 20A, and a control unit 50A are included instead of the transmission unit 10, the reception unit 20, and the control unit 50, and a transmission line 30 is included.

The transmission unit 10A is different from the transmission unit 10 (FIG. 1) in further including a switch 17. In this example, the switch 17 is connected to the PA 13, an antenna 14, and a transmission line 30. The switch 17 is switched between a state of connecting the PA 13 and the antenna 14 and a state of connecting the PA 13 and the transmission line 30.

The reception unit 20A is different from the reception unit 20 (FIG. 1) in further including a switch 27. In this example, the switch 27 is connected to an antenna 21, the LNA 22, and the transmission line 30. The switch 27 is switched between a state of connecting the antenna 21 and the LNA 22 and a state of connecting the antenna 21 and the transmission line 30.

The transmission line 30 is connected between the switch 17 and the switch 27. The transmission line 30 is a line provided on the radar device 1A so as to transmit the FMCW signal. In order to make the FMCW signal from the PA 13 a signal suitable for the input of the LNA 22, for example, an attenuator (not illustrated) or the like may be provided on the transmission line 30.

The switch 17, the transmission line 30, and the switch 27 constitute a bypass line for the FMCW signal. This bypass line connects a portion (on the side of the multiplier 11) before the antenna 14 in the transmission path of the transmission unit 10 and a portion (on the side of the ADC 26) after the antenna 21 in the reception path of the reception unit 20. Such a bypass line bypasses at least a path passing through the antenna 14 and the antenna 21 (and the object 60) among paths of the FMCW signal from the transmission unit 10 to the reception unit 20.

The control unit 50A is different from the control unit 50 (FIG. 1) in further controlling the switch 17 and the switch 27. For example, the control unit 50A may control the switch 17 and the switch 27 such that the FMCW signal from the PA 13 is supplied to the antenna 14 via the switch 17, and the FMCW signal from the antenna 21 is input into the LNA 22 via the switch 27. In this case, the operation similar to that of the radar device 1 can be performed. Furthermore, the control unit 50A may control the switch 17 and the switch 27 such that the FMCW signal from the PA 13 is input into the LNA 22 via the switch 17, the transmission line 30, and the switch 27. In this case, the spurious measurement unit 52 measures the spurious of the FMCW signal input from the transmission unit 10 into the reception unit 20 via the switch 17, the transmission line 30, and the switch 27 (i.e., the bypass line). That is, the spurious of the FMCW signal before being emitted from the antenna 14 is measured.

In the example illustrated in FIG. 7, the switch 17, the switch 27, and the transmission line 30 are provided between the PA 13 and the LNA 22, but the switch 17, the switch 27, and the transmission line 30 may be provided so as to connect an arbitrary position of the transmission unit 10 before the antenna 14 and an arbitrary position of the reception unit 20 before the ADC 26. Furthermore, the switch 17, the switch 27, and the transmission line 30 are merely examples of the bypass line, and the bypass line may be configured by various other elements.

### 3. Effects

The radar device described above is specified as follows, for example. As illustrated in FIG. 1 and the like, the radar device 1 includes the transmission unit 10, the reception unit 20, the spurious measurement unit 52, and the signal control unit 51. The transmission unit 10 transmits the FMCW signal. The reception unit 20 receives the FMCW signal which is transmitted by the transmission unit 10 and reflected by the object 60. The spurious measurement unit 52 measures the spurious of the FMCW signal. The signal control unit 51 controls the FMCW signal transmitted by the transmission unit 10 on the basis of the measurement result of the spurious measurement unit 52.

According to the above radar device, the FMCW signal is controlled on the basis of the spurious measurement result of the FMCW signal. Accordingly, the spurious characteristic can be improved (e.g., the spurious caused by a frequency error of the FMCW signal can be suppressed). Therefore, for example, a simple spurious method without enlarging the circuit scale or increasing the power consumption is realized. It is also possible to cope with widening of a sweep bandwidth, shortening of a sweep time (acceleration of sweep), and the like.

The signal control unit 51 may change the parameter of the FMCW signal. For example, in this way, the FMCW signal can be controlled.

The signal control unit 51 may select a parameter having the best spurious characteristic within the range of the measurement result of the spurious measurement unit 52 from a plurality of predetermined parameters. As a result, the best spurious characteristic can be obtained within the range of the result of the spurious measurement unit 52.

As illustrated in FIG. 3 and the like, the FMCW signal may be a chirp signal. The type of the parameter may include at least one of a sweep bandwidth, a sweep time, or a center frequency. The value of the parameter may include at least one of a magnitude of a sweep bandwidth, a length of a sweep time, or a value of a center frequency. For example, the FMCW signal can be controlled by varying the values of such various types of parameters.

The value of the parameter may be a shift amount. The value of the parameter can be changed by changing the shift amount in this manner. When the shift amount is a minute amount, the signal processing circuit (a circuit after the multiplier 11) at the subsequent stage can operate without being affected by the shift amount, and thus there is also an advantage that mounting on the radar device becomes easy.

As illustrated in FIGS. 1 and 2 and the like, the radar device 1 may further include the VCO 450 for generating an FMCW signal. The signal control unit 51 may control the modulation frequency of the VCO 450 by using the frequency DAC 451. As a result, the spurious caused by a frequency error in the VCO 450 can be suppressed. In particular, in a case of a frequency synthesizer in which the VCO 450 is configured as a two-point modulation, the spurious is likely to occur as described above, and thus the advantage of spurious suppression is large.

As illustrated in FIG. 1 and the like, the transmission unit 10 may include the antenna 14 that emits an FMCW signal. The reception unit 20 may include the antenna 21 that receives the FMCW signal which is emitted by the transmission unit 10 and reflected by the object 60. The spurious measurement unit 52 may measure the spurious of the FMCW signal after received by the antenna 21. For example, in this manner, the spurious of the FMCW signal can be measured.

As illustrated in FIG. 7 and the like, the radar device 1 may include the bypass line (In this example, the switch 17, the transmission line 30, and the switch 27). This bypass line connects a portion (on the side of the multiplier 11) before the antenna 14 in the transmission path of the transmission unit 10 and a portion (on the side of the ADC 26) after the antenna 21 in the reception path of the reception unit 20. The spurious measurement unit 52 may measure the spurious of the FMCW signal input from the transmission unit 10 into the reception unit 20 via the bypass line. Accordingly, for example, the spurious of the FMCW signal can be measured without emitting the FMCW signal from the antenna 14.

For example, spurious suppression processing (a method for controlling a radar device) illustrated in FIG. 6 and the like is also an aspect of the present embodiment. That is, the method for controlling the radar device 1 that transmits and receives the FMCW signal includes measuring the spurious of the FMCW signal (Step S5) and controlling the FMCW signal on the basis of the measured spurious (Step S8). According to such a control method, spurious characteristics can be improved similarly to the radar device 1 described above.

Note that the effects described in the present disclosure are merely examples and are not limited to the disclosed contents. There may be other effects.

Although the embodiments of the present disclosure have been described above, the technical scope of the present disclosure is not limited to the above-described embodiments as it is, and various modifications can be made without departing from the gist of the present disclosure. Moreover, components of different embodiments and modification examples may be combined as appropriate.

Furthermore, the effects of each embodiment described in the present specification are merely examples and are not limited, and other effects may be exerted.

Note that the present technology can also adopt the following configurations.
(1) A radar device including:
   a transmission unit that transmits a frequency modulated continuous wave (FMCW) signal;
   a reception unit that receives the FMCW signal which is transmitted by the transmission unit and reflected by an object;
   a measurement unit that measures a spurious of the FMCW signal; and
   a signal control unit that controls, on the basis of a measurement result of the measurement unit, the FMCW signal transmitted by the transmission unit.
(2) The radar device according to (1), in which
   the signal control unit changes a parameter of the FMCW signal.
(3) The radar device according to (2), in which
   the signal control unit selects a parameter with which a spurious characteristic is best within a range of the measurement result from a plurality of predetermined parameters.
(4) The radar device according to (2) or (3), in which
   the FMCW signal is a chirp signal, and
   a type of the parameter includes at least one of a sweep bandwidth, a sweep time, or a center frequency.
(5) The radar device according to (4), in which
   a value of the parameter includes a magnitude of the sweep bandwidth.
(6) The radar device according to (4) or (5), in which
   a value of the parameter includes a length of the sweep bandwidth.
(7) The radar device according to any one of (4) to (6), in which
   a value of the parameter includes a value of the center frequency.
(8) The radar device according to any one of (5) to (7), in which
   the value of the parameter includes a shift amount.
(9) The radar device according to any one of (1) to (8), further including a VCO for generating the FMCW signal, in which
   the signal control unit controls a modulation frequency of the VCO by using a frequency DAC.
(10) The radar device according to any one of (1) to (9), in which
   the transmission unit includes a transmission antenna that emits the FMCW signal,
   the reception unit includes a reception antenna that receives the FMCW signal which is emitted by the transmission antenna and reflected by the object, and
   the measurement unit measures the spurious of the FMCW signal after received by the reception antenna.
(11) The radar device according to any one of (1) to (9), in which
   the transmission unit includes a transmission antenna that emits the FMCW signal,
   the reception unit includes a reception antenna that receives the FMCW signal which is emitted by the transmission antenna and reflected by the object,
   the radar device further comprises a bypass line that connects a portion before the transmission antenna in a transmission path of the transmission unit and a portion after the reception antenna in a reception path of the reception unit, and
   the measurement unit measures the spurious of the FMCW signal input from the transmission unit into the reception unit via the bypass line.
(12) A method for controlling a radar device that transmits and receives an FMCW signal, the method including:
   measuring a spurious of the FMCW signal; and
   controlling the FMCW signal on the basis of the spurious measured.

### REFERENCE SIGNS LIST

1 Radar device
10 Transmission unit
11 Multiplier
12 Buffer
13 PA
14 Antenna
17 Switch
20 Reception unit
21 Antenna
22 LNA
23 Multiplier
24 Mixer
25 Filter
26 ADC
27 Switch
30 Transmission line
40 PLL
50 Control unit
51 Signal control unit
52 Spurious measurement unit
60 Object
410 FMCW signal generator
420 DTC control unit
430 DTC
440 Frequency DAC control unit
450 VCO
451 Frequency DAC
452 VCO core
461 Buffer
462 Switch
463 Capacitor
464 Converter
465 Loop filter
466 Start-up PLL

What is claimed is:

1. A radar device comprising:
a transmission unit that transmits a frequency modulated continuous wave (FMCW) signal;
a reception unit that receives the FMCW signal which is transmitted by the transmission unit and reflected by an object;
a measurement unit that measures a spurious of the FMCW signal; and
a signal control unit that controls, on a basis of a measurement result of the measurement unit, the FMCW signal transmitted by the transmission unit.

2. The radar device according to claim 1, wherein
the signal control unit changes a parameter of the FMCW signal.

3. The radar device according to claim 2, wherein
the signal control unit selects a parameter with which a spurious characteristic of the FMCW signal is best within a range of the measurement result from a plurality of predetermined parameters.

4. The radar device according to claim 2, wherein
the FMCW signal is a chirp signal, and
a type of the parameter includes at least one of a sweep bandwidth, a sweep time, or a center frequency.

5. The radar device according to claim 4, wherein
a value of the parameter includes a magnitude of the sweep bandwidth.

6. The radar device according to claim 4, wherein
a value of the parameter includes a length of the sweep bandwidth.

7. The radar device according to claim 4, wherein
a value of the parameter includes a value of the center frequency.

8. The radar device according to claim 5, wherein
the value of the parameter includes a shift amount.

9. The radar device according to claim 1, further comprising a VCO for generating the FMCW signal,
wherein
the signal control unit controls a modulation frequency of the VCO by using a frequency DAC.

10. The radar device according to claim 1, wherein
the transmission unit includes a transmission antenna that emits the FMCW signal,
the reception unit includes a reception antenna that receives the FMCW signal which is emitted by the transmission antenna and reflected by the object, and
the measurement unit measures the spurious of the FMCW signal after received by the reception antenna.

11. The radar device according to claim 1, wherein
the transmission unit includes a transmission antenna that emits the FMCW signal,
the reception unit includes a reception antenna that receives the FMCW signal which is emitted by the transmission antenna and reflected by the object,
the radar device further comprises a bypass line that connects a portion before the transmission antenna in a transmission path of the transmission unit and a portion after the reception antenna in a reception path of the reception unit, and
the measurement unit measures the spurious of the FMCW signal input from the transmission unit into the reception unit via the bypass line.

12. A method for controlling a radar device that transmits and receives an FMCW signal, the method comprising:
measuring a spurious of the FMCW signal; and
controlling the FMCW signal on a basis of the spurious measured.
